(19) United States
(12) Patent Application Publication
(10) Pub. No.: US 2019/0214235 A1
(43) Pub. Date: Jul. 11, 2019

(54) PLASMA PROCESSING APPARATUS

(71) Applicant: HITACHI HIGH-TECHNOLOGIES CORPORATION, Tokyo (JP)

(72) Inventors: Kenetsu YOKOGAWA, Tokyo (JP); Masakazu ISOZAKI, Tokyo (JP); Yousuke SAKAI, Tokyo (JP); Masahito MORI, Tokyo (JP); Takao ARASE, Tokyo (JP)

(21) Appl. No.: 16/113,913

(22) Filed: Aug. 27, 2018

(30) Foreign Application Priority Data
Jan. 11, 2018 (JP) 2018-002311

(51) Int. Cl. H01J 37/32; H01L 21/683; H01L 21/687; C23C 4/02

(52) U.S. Cl. CPC H01J 37/32532; H01L 21/6833; H01J 37/32082; C23C 4/02; H01J 37/32715; H01L 21/6875

(57) ABSTRACT

Provided is a plasma processing apparatus in which a sample as a processing target placed and held on a sample stage is processed using plasma formed inside a processing chamber, the sample stage being disposed inside the processing chamber inside a vacuum chamber, wherein a plate-like member, which is disposed on the sample stage, constitutes a top surface placed with the sample, and is formed of a first dielectric, includes: an outer circumferential protruding portion disposed in a ring shape surrounding a central portion on the top surface of the plate-like member along an outer circumferential edge; a plurality of columnar projections which are arranged on the top surface of the plate-like member on the central side of the outer circumferential protruding portion; and a film formed of a second dielectric which covers the top surface of the plate-like member on the central side of the outer circumferential protruding portion, a top-portion top surface of the projections, and a top surface of the plate-like member excluding a sidewall surface extending from an outer circumferential edge of the top-portion top surface.

### CROSS-REFERENCE TO RELATED APPLICATIONS

The present application claims priority to Japanese Patent Application No. 2018-002311, filed Jan. 11, 2018. The contents of this application are incorporated herein by reference in their entirety.

### BACKGROUND OF THE INVENTION

### 1. Field of the Invention

The present invention relates to a plasma processing apparatus for processing a base material-like sample such as a semiconductor wafer disposed in a processing chamber inside a vacuum chamber by using plasma formed in the processing chamber, and particularly relates to a plasma processing apparatus that performs etching processing on a sample disposed inside a processing chamber while adsorbing the sample onto a dielectric film on the top surface of a sample stage to be held.

### 2. Description of Related Art

Plasma processing represented by dry etching is a technique for obtaining a circuit having a desired shape from a film structure in a way that, while introducing processing gas into a processing chamber inside a vacuum chamber to which an exhaust device is connected, atoms or molecules of the processing gas are excited by an electric field or a magnetic field supplied into the processing chamber to be ionized or dissociated to form plasma, and a film layer to be processed which is not covered with a mask layer having a film structure including a mask layer previously arranged on the sample surface and a film layer to be processed is processed using the particles in the plasma. As a method of generating such plasma, an inductive coupling method, an electron cyclotron resonance method, and a parallel plate method (including a magnetron method) are mainly used.

High-frequency power of 13.56 MHz is mainly used for generation of plasma by an inductive coupling method and a magnetic field of a micro wave band of 2.45 GHz is mainly used for generation of plasma by an electron cyclotron resonance method. In these inductive coupling method and electron cyclotron resonance method, in order to control the energy of charged particles such as ions incident on the surface of the sample to be processed, separately from the plasma generation, an electric field in a radio frequency (RF) band is supplied to the sample or the electrode inside the sample stage supporting the sample, and the reaction of the reactive particles in the plasma with respect to the film to be processed is promoted by the collision with charged particles induced in a direction of the sample surface by the potential difference between the bias potential formed above the sample surface and the potential of plasma, thereby progressing the process.

In the parallel plates method, according to the related art, a high-frequency power of 13.56 MHz is supplied to any one of the flat plate-like electrodes arranged facing each other, but recently, an electric field of a frequency of VHF band (30 MHz to 300 MHz) is increasingly used. Similarly to the inductive coupling method and the electron cyclotron resonance method, a radio frequency (RF) power for independently controlling the energy of charged particles such as ions incident on the surface of the sample is also used separately from plasma generation.

As the electric field of high frequency power used for adjusting the energy of charged particles incident on the sample surface separately from the electric field used for the formation of plasma, is an electric field of a frequency of a few hundred kHz to a few MHz has been used in the related art. However, in order to improve the controllability of energy, there is a tendency to use an electric field having a frequency of the MHz band or higher.

On the other hand, in a plasma processing apparatus in which a sample to be processed (hereinafter referred to as a sample) is placed inside a vacuum chamber, a sample stage for holding the sample above from a top surface thereof, and a refrigerant whose temperature is controlled by a temperature control device disposed outside the vacuum chamber is supplied to a channel inside the sample stage and is circulated. Alternatively, a heating device such as a heater is disposed inside the sample stage. With these configurations, the temperature of the sample stage is adjusted to a value within a desired range of a user.

In the related art, in such a configuration of the sample stage, in order to set the temperature of the sample stage whose temperature has been adjusted in advance to a value within the range suitable for processing with high accuracy of the sample being processed using plasma, a configuration is provided that a sample placed on the top surface thereof is adsorbed and held on the top surface of the sample stage by using electrostatic force and a gas such as He having heat transferability is supplied to a gap between the top surface and the back surface of the sample to promote heat transfer between the sample and the sample stage.

In the related art, as a configuration for generating electrostatic force for adsorbing a sample on the top surface of the sample stage, there is known a configuration in which a film formed by thermal spraying a ceramic material such as alumina (aluminum oxide) on the top surface of a base material of the sample stage, or direct current power is supplied to a film-like adsorption electrode disposed inside a sintered body which is a member formed by sintering a ceramic material and adhered on the top surface of the base material. Furthermore, as a configuration for achieving such electrostatic attraction (electrostatic adsorption), a Coulomb method using ceramics such as aluminum oxide having very high resistivity, and a Johnson-Rahbek system in which adsorption is performed while flowing a direct current having relatively low resistivity of about from several-hundred micro amperes to one milliampere are known.

Further, there are a dipole type in which a plurality of electrodes for electrostatic adsorption are disposed in a film made of a dielectric material such as ceramics or a sintered plate, DC power is supplied so that different polarities are imparted to these electrodes, thereby absorbing the sample and a monopole type which adsorbs a sample by imparting positive or negative polarity to the electrode. In a case of using a Coulomb type, a configuration can be made in which a plurality of protrusions (dots) having minute dimensions are arranged on the surface of a dielectric film so that the back surface of the sample can be held in contact with the top surface of the protrusion, whereby it is possible to reduce the area where the sample comes in contact with the top surface of the sample stage and to prevent adhesion or generation of foreign matters on the back surface of the sample due to the contact.

In general, in a plasma processing apparatus, in order to control the temperature of a sample and its in-plane distribution precisely, the electrostatic force for electrostatically adsorbing the sample on the top surface of the sample stage needs to be sufficiently increased compared to the force due to the pressure of gas such as He or the like introduced into the gap between the sample and the top surface of the sample stage to absorb the sample strongly on the top surface of the sample stage.

Incidentally, there is a possibility that the member on the surface of both the sample and the sample stage may be damaged when the back surface of the sample comes into contact with the top surface of the sample stage, or the particles attached to one of the surfaces may reattach to the other and become foreign matters. The foreign matter may not only adhere to the sample but also adhere to the case for the sample to which the sample after processing using the plasma is returned or but also adhere again on the surface of another sample on which the fine circuit is formed in the subsequent step, resulting in contamination due to foreign matter is increased and the yield of processing in the plasma processing apparatus is degraded.

In order to solve such problems, a plurality of protrusions (dots) having a predetermined height, for example, a height of about several micrometers, are formed in advance on the top surface of the sample stage on which the sample is electrostatically adsorbed, and the sample placed on the top surface of the sample stage is held in contact with the top surfaces of these protrusions from the back surface thereof, so that it is possible to reduce the area where the sample is in contact with the top surface of the sample stage while maintaining the electrostatic adsorption force to prevent occurrence of problems caused by the foreign matter.

As an example of the related art, a plasma processing apparatus disclosed in JP-A-2015-162490 has been known. This related art discloses an example of a plasma processing apparatus which processes a wafer W by forming plasma between the upper electrode disposed in the upper portion of the vacuum chamber inside the processing chamber in a vacuum chamber in which a mounting table for holding the wafer W as an object to be processed is disposed and the lower electrode in the mounting stage inside the processing chamber. The top surface of the base portion constituting the mounting stage of the corresponding plasma processing apparatus is disposed with an electrostatic chuck, and upper and lower dielectric layers constituting the electrostatic chuck and electrodes disposed therebetween, and a plurality of protrusions arranged on the flat top surface of the upper dielectric layer are provided.

Further, in the corresponding related art, the plasma processing apparatus includes a protective film made of a material including yttria arranged to cover the top surface of the dielectric layer and the protruding portion. In such a configuration, the protective film covers the flat top surface of the dielectric layer and the side wall surfaces of the plurality of protruding portions protruding above the top surface, thereby preventing generation of particles.

However, in the above related art, since consideration on the following points was insufficient, problems have arisen.

That is, since the force is concentrated on the top surface of the protrusion by electrostatic attraction of the sample, mechanical strength is also required for the protrusion to prevent damage during adsorption and to prevent the generation of particles and foreign matter. Furthermore, in recent years, for the purpose of increasing the mass productivity of a plasma processing apparatus, in order to prevent a deposit formed by deposition of a product generated as a result of processing of a sample using a plasma on a surface inside the vacuum chamber from adhering during sample replacement or other sample processing resulting in the increase of contaminants, a cleaning process using plasma is used to remove deposits and deposits on the interior surface of the vacuum chamber where the sample is processed after the processing of an arbitrary sample and before the processing of the next sample.

Even in the so-called waferless case in which the sample is not placed on the top surface of the sample stage in such a cleaning process, there is a concern that the period until the performance, which electrostatically absorbs the material on the top surface of the sample stage is consumed by the plasma for cleaning, deteriorates is shortened or metal contamination occurs due to aluminum oxide consumed in the vacuum chamber.

To cope with such a problem, as disclosed in PTL 3, it is possible to prevent wear and contamination by covering or constituting the surface of a dielectric member for electrostatic adsorption of a sample or its specific portion with yttria or its compound such as yttrium oxide (Y₂O₃). It has been found that as high as yttrium oxide in plasma resistance (in particular, plasma with fluoride radicals), yttrium oxide is rarely consumed, and it can be considered that the dielectric member for electrostatic adsorption covered with a film made of such a material is prevented from being degraded in performance and contamination inside the vacuum chamber or sample due to metal elements contained in the dielectric member such as alumina is prevented.

However, the related art has not taken into account the problem that since yttrium oxide is weak in mechanical strength with respect to aluminum oxide used in related art, even if it is possible to prevent deposits on the back surface of the sample by covering the side wall surface of the protruding portion on the top surface of the sample stage on which the sample is placed or on the flat surface of the top surface between the protrusions, due to deformation of the protruding portion occurred in a state where the top surface of the protruding portion comes into contact with the sample and the electrostatic force for adsorbing the sample is applied to the protrusion, the coating film of yttrium oxide may be damaged or broken to generate particles from the top surface of the sample stage which is supposed to be prevented, and to cause foreign matter to be generated due to attachment of particles and fragments to the back surface of the sample, whereby the yield of processing deteriorates.

### SUMMARY OF THE INVENTION

An object of the present invention is to provide a plasma processing apparatus in which the yield of processing is improved.

The object described above will be achieved with a plasma processing apparatus in which a sample as a processing target placed and held on a sample stage is processed using plasma formed inside a processing chamber, the sample stage being disposed inside the processing chamber inside a vacuum chamber, wherein

a plate-like member, which is disposed on the sample stage, constitutes a top surface placed with the sample, and is formed of a first dielectric, includes: an outer circumferential protruding portion disposed in a ring shape surrounding a central portion on the top surface of the plate-like member along an outer circumferential edge; a plurality of columnar projections which are arranged on the top surface of the plate-like member on the central side of the outer circumferential protruding portion; and a film formed of a second dielectric which covers the top surface of the plate-like member on the central side of the outer circumferential protruding portion, a top-portion top surface of the projections, and a top surface of the plate-like member excluding a sidewall surface extending from an outer circumferential edge of the top-portion top surface.

The present invention relates to an electrostatic adsorption mechanism part for adsorbing a sample on a sample stage in the plasma processing apparatus described in the “Description of Related Art” above.

In the invention, a main material of an insulator used for electrostatic adsorption is formed of aluminum oxide, and a dot portion for reducing the contact area on the aluminum oxide surface is formed at 3% or less in total area, further, yttrium oxide was coated at 4 to 10 μm in addition to a partial region including the dot region or the dot region on the surface of the aluminum oxide, and 90% or more of the surface of the electrostatic adsorption part was covered with yttrium oxide.

### Advantageous Effects of Invention

According to the invention, the electrostatic adsorption surface is almost covered with yttrium oxide, so that it is possible to prevent metal contamination caused by aluminum oxide due to consumption and consumption due to plasma irradiation. Furthermore, mechanical failure and wear of yttrium oxide can be avoided by not disposing yttrium oxide having low mechanical strength on the dot portion or the dot portion and a part therearound where the mechanical stress concentrates upon contact with the sample.

### BRIEF DESCRIPTION OF THE DRAWINGS

FIG. 1 is a view for describing an outline of a configuration of a plasma processing apparatus according to an embodiment of the present invention;

FIGS. 2A and 2B are longitudinal cross-sectional views schematically illustrating the outline of the configuration of the sample stage of the plasma processing apparatus according to the embodiment illustrated in FIG. 1;

FIG. 3 is a view schematically illustrating the outline of the configuration of the sample stage of the present embodiment illustrated in FIGS. 2A and 2B;

FIG. 4 is an enlarged longitudinal sectional view schematically illustrating a part of the structure of an electrostatic chuck of a sample stage of a plasma processing apparatus according to a modification of the above-described embodiment of the invention illustrated in FIG. 1; and

FIG. 5 is an enlarged longitudinal sectional view schematically illustrating a part of the structure of an electrostatic chuck of a sample stage of a plasma processing apparatus according to another modification of the above-described embodiment of the invention illustrated in FIG. 1.

### DESCRIPTION OF EMBODIMENTS

Hereinafter, an embodiment of the invention will be described with reference to the drawings.

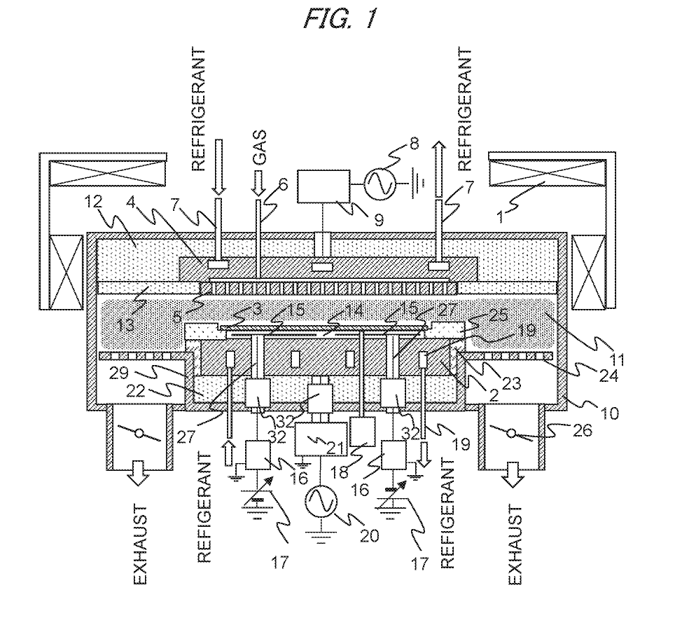

The embodiment of the invention will be described with reference to FIGS. 1 to 4. FIG. 1 is a view for describing the outline of a configuration of a plasma processing apparatus according to the embodiment of the present invention.

The plasma processing apparatus in FIG. 1 is a plasma processing apparatus of magnetic field parallel plate type using an electromagnetic coil 1 as a solenoid coil. The plasma processing apparatus in the present embodiment includes a vacuum chamber 10 and a processing chamber arranged in an upper portion thereof and in which a sample to be processed is mounted in a space inside the vacuum chamber 10 and plasma is formed after a gas for processing being supplied, and also includes a plasma forming unit as an apparatus arranged above the vacuum chamber 10 to generate an electric field or a magnetic field to form plasma inside the processing chamber and an exhaust apparatus connected to a lower portion of the vacuum chamber 10 and including a vacuum pump such as a turbo-molecular pump that reduces pressure by exhausting air inside the processing chamber.

In the processing chamber inside the vacuum chamber 10, a sample stage 2 arranged in a lower portion thereof and having a cylindrical shape, an upper electrode 4 in a disc shape to which high-frequency power to form plasma is supplied by being arranged above and opposite to the sample stage 2, and a shower plate 5 in a disc shape arranged on the sample 3 side of the upper electrode 4 and opposite to a mounting surface of the sample stage 2 and including a plurality of through holes constituting a ceiling surface of the processing chamber to supply a gas into the processing chamber in a distributed manner are disposed. In addition, a base material-like sample 3 such as a semiconductor wafer is placed and held on the mounting surface of the sample stage 2.

The shower plate 5 and the upper electrode 4 as an antenna arranged above the shower plate 5 are arranged such that a gap is formed therebetween when mounted inside the vacuum chamber 10.

The gap is connected to the gas introduction line 6 outside the vacuum chamber 10 and the gas channel provided in the upper electrode 4, and these members communicate with each other as a gas supply path into the processing chamber.

In the present embodiment, the processing gas used for the processing of the sample 3 supplied into the processing chamber, or an inert gas, which is not directly used for the processing but is supplied to the inside of the processing chamber and is replaced with the processing gas when diluting the processing gas or not supplying the processing gas, is supplied to the gap from the gas introduction line 6 through the gas channel provided in the upper electrode 4 and dispersed therein, and then supplied to the inside of the processing chamber through the plurality of through holes disposed in the region including the central portion of the shower plate 5.

The upper electrode 4 is a disc-shaped member made of a metal material such as aluminum or stainless steel which is a conductive material, and a coaxial cable to which high-frequency power for plasma formation is transmitted is electrically connected to the center portion of the top surface of the upper electrode 4. Further, the upper electrode 4 is connected to a temperature control device such as a chiller for adjusting the temperature of the refrigerant to a predetermined range, and includes an upper electrode refrigerant channel 7 to which the refrigerant is supplied. The temperature of the upper electrode 4 is regulated within a value range suitable for processing by exchanging heat while the refrigerant circulates inside the upper electrode refrigerant channel 7.

The high-frequency power for plasma formation is supplied to the upper electrode 4 of the present embodiment from a high-frequency power supply for discharge 8 electrically connected thereto via the coaxial cable via a high-frequency power matching box for discharge 9.

The shower plate 5 is a member formed of a dielectric such as quartz or a semiconductor formed of silicon or the like having a top surface in a shape of a disk. As a result of application of high-frequency power to the upper electrode 4, an electric field emitted from the surface of the upper electrode 4 forms an electric field on the surface of the shower plate 5 or permeates the shower plate 5, so that an electric field is discharged into the processing chamber. Further, in the present embodiment, the magnetic field formed by the electromagnetic coil 1 disposed surrounding the upper part and the side part of the upper portion of the processing chamber outside the vacuum chamber 10 is supplied to the inside of the processing chamber.

By the interaction between the magnetic field and the high frequency electric field, atoms or molecules of the processing gas or inert gas supplied to the inside of the processing chamber are excited and ionized or dissociated to form the plasma 11 in the processing chamber. In the present embodiment, electric power of 200 MHz, which is the frequency of the superhigh frequency band (VHF band), is used as the high frequency electric power for forming the plasma.

Between the lid member constituting the upper portion of the vacuum chamber 10 and opening and closing the vacuum chamber 10 and the upper electrode 4 arranged inside the vacuum chamber 10, there is disposed a ring-shaped upper electrode insulator 12 disposed on the upper side or the side of the upper electrode 4 and formed of a dielectric such as quartz and Teflon (registered trademark). The upper electrode insulator 12 electrically insulates the upper electrode 4 from a lid member constituting the upper part of the vacuum chamber 10 and opening and closing the vacuum chamber 10.

Similarly, an insulating ring 13 made of a dielectric such as quartz is disposed around the shower plate 5 and insulated from the lid member. The upper electrode insulator 12, the insulating ring 13, the upper electrode 4, and the shower plate 5 rotate integrally with the lid member during the opening and closing operation of the lid member.

The vacuum chamber 10 having a cylindrical shape is connected to a transport chamber which is a vacuum chamber with side walls not illustrated and through which the sample 3 is transported in a transfer chamber as a depressurized internal space. A passage through which the sample 3 is taken in and out is arranged between the vacuum chamber and the transport chamber. Inside the transfer chamber, a gate as an opening of the passage and a gate valve which abuts against the side wall of the transfer chamber around the gate and opens and closes the gate are arranged. The gate valve is configured to be movable in the vertical direction with respect to the gate, and is provided with a seal member such as an O-ring on the surface abutting against the inside wall of the transfer chamber, and when the sample 3 transported into the vacuum chamber 10 is processed, the O-ring is brought into contact with the inner side wall of the transfer chamber surrounding the gate by moving in the vertical direction to close the gate, thereby airtightly sealing the inside of the vacuum chamber 10 and the passage with respect to the transfer chamber.

An evacuation opening communicating with a vacuum pump for exhausting the interior of the processing chamber is disposed in a lower portion of the vacuum chamber 10 below the sample stage 2 in the processing chamber. On the exhaust pipeline connecting the exhaust opening and the vacuum pump to each other, a pressure regulating valve 26 as a plate-like valve is disposed to increase or decrease the sectional area in the direction of exhaust of the channel by crossing the channel for exhaust thereinside and rotating around the axis.

The plate-like member of the pressure regulating valve 26 is rotated so that the angle is adjusted and the sectional area is increased or decreased. As a result, the flow rate or speed of the exhaust gas from the processing chamber is increased or decreased. In the present embodiment, the pressure inside the processing chamber is controlled by a control device (not illustrated) so as to be within a range of a desired value with a balance between the flow rate or speed of the gas supplied from the through hole of the shower plate 5 and the flow rate or speed of the gas or particles discharged from the exhaust opening.

Next, the structure around the sample stage 2 will be described. The sample stage 2 in this embodiment is a stage having a cylindrical shape disposed in the lower center on the processing chamber, and includes a metal base material 2a having a cylindrical shape or a disc shape thereinside. The base material 2a in this embodiment is electrically connected to a high-frequency power supply for bias 20 by a feeding path including a coaxial cable via a high-frequency power matching box for bias 21 disposed on the feeding path.

With this configuration, another high-frequency power with a frequency (4 MHz in this example) different from that of the high-frequency power for plasma formation is supplied to the base material 2a. A bias potential is formed above the top surface of the sample 3 or the sample mounting surface by the high-frequency power supplied to the base material 2a to attract a charged particle such as an ion in the plasma to the top surface of the sample 3 or the sample mounting surface. In other words, the base material 2a functions as a lower electrode applied with the high-frequency power for bias below the upper electrode 4.

Inside the base material 2a, a refrigerant channel 19 is arranged multiple-concentrically or spirally. The refrigerant channel 19 is supplied with a refrigerant of a predetermined temperature circulating and flowing therethrough to adjust the temperature of the base material 2a or the sample mounting surface to a temperature appropriate for processing.

The base material 2a is provided with an electrostatic adsorption film 14 formed of a dielectric such as alumina or yttria on the top surface thereof. In the electrostatic adsorption film 14, a film-shaped electrode 15 made of metal such as tungsten to which DC power is supplied for electrostatic adsorption of the sample 3. The back surface of the electrode 15 is electrically connected with the DC power supply 17 via the feeding path 27 disposed inside the through hole penetrating the base material 2a.

An element 32 such as a resistor or a coil is disposed below the base material 2a and on the feeding path 27 inside the sample stage 2, and the element 32 is connected to the grounded high-frequency power matching box for bias 21 and the high-frequency power supply for bias 20 through the high-frequency power matching box for bias 21 by a feeding path including the same coaxial cable as the high-frequency power supply for bias 20. Further, an element 32 such as a resistor or a coil is disposed below the through hole and on the feeding path 27 inside the sample stage 2, and the element 32 is connected to the DC power supply 17 via a low-pass filter 16.

In the DC power supply 17 and the high-frequency power supply for bias 20 of this embodiment, the terminal on one end side is grounded or is electrically connected to the ground.

The low-pass filter 16 and the high-frequency power matching box for bias 21 are disposed in order to prevent the inflow of high-frequency power for plasma formation from the high-frequency power supply for discharge 8 to the DC power supply 17 and the high-frequency power supply for bias 20. The DC power from the DC power supply 17 or the high-frequency power from the high-frequency power supply for bias 20 is supplied to the electrostatic adsorption film 14 and the sample stage 2 without loss by the low-pass filter 16 filtering while preventing the flow the current of higher frequency. However, the high-frequency power for plasma formation flowing from the sample stage 2 side to the DC power supply 17 and the high-frequency power supply for bias 20 is supplied to the ground via the low-pass filter 16 or the high-frequency power matching box for bias 21. Although the low-pass filter 16 is not illustrated in FIG. 1 on the feeding path from the high-frequency power supply for bias 20, a circuit having the same effect is incorporated in the high-frequency power matching box for bias 21 which is illustrated.

In the embodiment illustrated in FIG. 1, a plurality of film-like electrodes 15 are provided to be disposed inside the electrostatic adsorption film 14.

DC voltage is supplied to one and the other of the electrodes so as to each have different polarities, and electrostatic adsorption of both polarities is performed. For this reason, the electrodes 15 are arranged to be divided into two regions with a value within a range approximating to the extent that the area of the contact surface between the electrostatic adsorption film 14 and the sample 3 is divided into two or regarded value as this, DC power of independent values is supplied to each region, and the voltages are maintained at different values.

The sample stage 2 is provided with a through hole for heat transfer gas which is disposed to penetrate through the base material 2a and the electrostatic adsorption film 14 constituting the sample stage 2 and through which the heat transfer gas such as He passes. In the gap between the back surface of the sample 3, which is disposed above the top surface of the electrostatic adsorption film 14 to be electrostatically absorbed thereto, and the top surface of the electrostatic adsorption film 14, helium gas is supplied from the opening of the top surface of the electrostatic adsorption film 14 after passing through the inside of the through hole by the helium supply unit 18. Heat transfer between the sample 3 and the electrostatic adsorption film 14 is improved by the supplied helium gas having heat transferability and the amount of heat exchange with the refrigerant channel 19 inside the base material 2a is increased, thereby improving the efficiency of adjusting the temperature of the sample 3.

a disk-shaped insulating plate 22 formed of Teflon or the like is arranged below the base material 2a.

By disposing the insulating plate 22, the base material 2a, which is grounded or electrically connected with the ground to be set to be ground potential, is insulated from the lower member.

Furthermore, a ring-shaped insulating layer 23 formed of a dielectric such as alumina is disposed surrounding the periphery of the side surface of the base material 2a. Below the insulating plate 22 disposed to be connected to the base material 2a from below and the periphery thereof and the periphery of the above insulating layer 23, a conductive plate 29 is disposed which is grounded or electrically connected the ground to be set to be ground potential, and which is made of a conductive material.

The conductive plate 29 is a plate member having a shape approximate to the circular shape as viewed from above or regarded shape as this, and includes a concave portion which the base material 2a is disposed thereinside in the central portion thereof while interposing the insulating plate 22 and the insulating layer 23 so that the lower surface and the side surface of the base material 2a is disposed to be surrounded by the conductive plate 29. In addition, the conductive plate 29 includes a confinement plate 24 which is a plate-like flange portion extending in the horizontal direction from the central side to the outer circumferential side of the concave portion. The confinement plate 24 is disposed so as to bias the plasma formed above the sample stage 2 in the processing chamber to the upper part thereof for confining the plasma, and includes a plurality of holes to pass gas or the particles vertically to the plate-like flange portion.

In addition, a ring-shaped susceptor ring 25 made of a dielectric having plasma resistance, such as quartz, is disposed at a position on the outer circumferential side of the sample mounting surface having a substantially circular shape of the electrostatic adsorption film 14 above the sample stage 2, to be placed above the top surface of the outer circumferential portion of the base material 2a and surround the sample mounting surface. The outer circumferential edge of susceptor ring 25 is placed on the top surface of the insulating layer 23 so as to cover the same.

The conductive plate 29 and its outer circumferential side section, which is in the ground potential, includes the base material 2a and the ring-shaped insulating layer 23, and the disk-shaped insulating plate 22 disposed in contact with the lower surface thereof in the concave portion of the central portion, and placed such that a sidewall of a concave portion surrounds side surface of the insulating plate 22 and the insulating layer 23. The conductive plate includes the confinement plate 24 extending from the center side to the outer circumferential side and including a front end close to or in contact with the inner wall surface of the processing chamber of the vacuum chamber 10. The conductive plate 29 of the present embodiment, although not illustrated, is grounded or is electrically connected to the ground to be set to the ground potential.

The conductive plate 29 is made of a conductive material, but the confinement plate 24 facing plasma includes at least a member made of a conductive material such as aluminum and an alumina film formed by anodizing the surface thereof, or a film formed by melting a dielectric material such as ceramic. In addition, as described above, a plurality of gas passage holes 30 is formed in the confinement plate 24, and process gas supplied from the shower plate 5, or particles of plasma or the product in the processing chamber flows into the internal space of the processing chamber of the outer circumferential side of the sample stage 2 through the inside of the gas passage holes 30 toward the exhaust opening located below the sample stage 2.

In addition, on the feeding path including a power supply path 27 for electrically connecting the DC power supply 17 for electrostatic adsorption and the electrode 15 made of tungsten, and a coaxial cable for electrically connecting the high-frequency power supply for bias 20 and the base material 2a, the element 32 including a resistor or a coil is disposed. In the present embodiment, on the feeding path 27, the element 32 disposed between the low-pass filter 16 and the tungsten electrode 15 on the feeding path 27 is composed of a resistor of 1000Ω, and on the feeding path between the high-frequency power supply for bias 20 and the base material 2a, the element 32 disposed between the high-frequency power matching box for bias 21 and the base material 2a is a material, such as a coil, having inductance 0.5 μH (having an impedance of 628Ω with respect to power of 200 MHz used for high-frequency power for plasma formation).

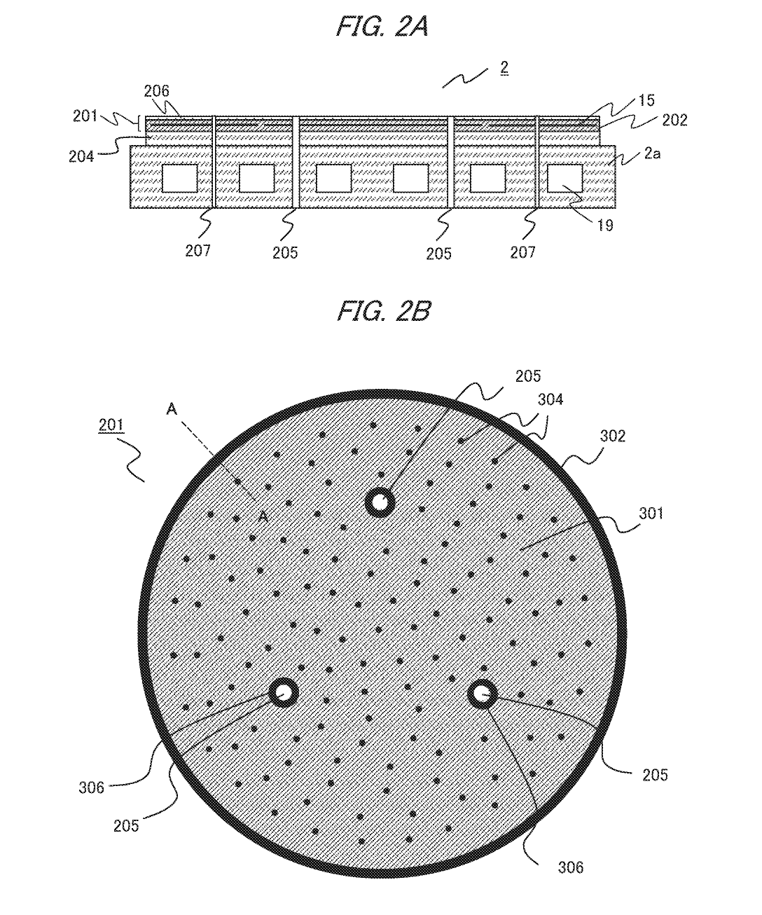

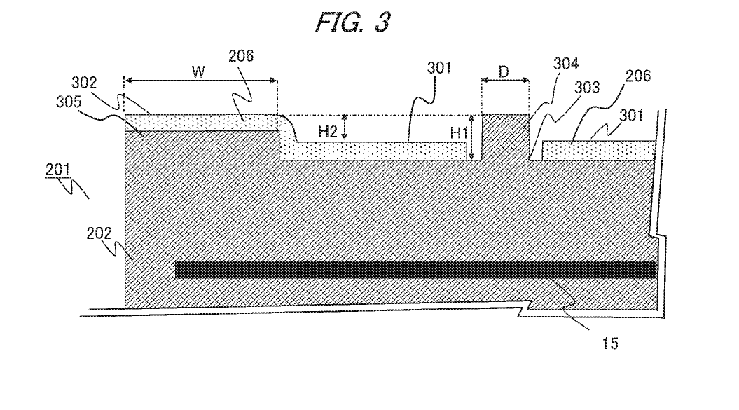

The configuration of the sample stage of the present invention will be described with reference to FIGS. 2A and 2B and 3. FIGS. 2A and 2B are longitudinal cross-sectional views schematically illustrating the outline of the configuration of the sample stage of the plasma processing apparatus according to the embodiment illustrated in FIG. 1. FIG. 3 is a view schematically illustrating the outline of the configuration of the sample stage of the present embodiment illustrated in FIGS. 2A and 2B. FIG. 2B is a top view when viewing the top surface of the sample stage 2 from the top, and FIG. 3 is a longitudinal cross-sectional view taken along line A-A of FIG. 2B.

In the example illustrated in FIGS. 2A and 2B, the configuration of the base material 2a as a main part of the sample stage 2 and the electrostatic chuck 201 disposed above the top surface thereof is illustrated in an enlarged manner, but other members are also disposed as members constituting the sample stage 2 in the embodiment illustrated in FIG. 1, and thus these members are omitted in FIGS. 2A and 2B.

In the example illustrated in FIGS. 2A and 2B, the base material 2a, which is formed of metal having a cylindrical shape or a disk shape and is disposed inside the sample base 2, is connected by the feeding path composed of the coaxial cable or the like, through the high-frequency power supply for bias 20 and the bias high-frequency power matcher 21 not illustrated. In addition, in the base material 2a, a refrigerant channel 19, in which refrigerant whose temperature is adjusted by a temperature adjuster not illustrated flows, is coaxially or spirally disposed around the center of the base material 2a. In this example, the temperature of the base material 2a or the sample stage 2 is adjusted only by circulating the refrigerant whose temperature is adjusted in the refrigerant channel 19 in the sample stage 2, but a heating or temperature adjustment units such as a heater may be disposed between the refrigerant channel 19 in the base material 2a and the electrostatic chuck 201 placed on the base material 2a.

On the top surface of the base material 2a, the electrostatic chuck 201 including a plate-shaped member having a circular shape or a shape similar thereto is disposed with an adhesive layer 204 made of resin interposed between the top surface of the base material 2a and the electrostatic chuck 201, which are electrically connected to each other. In addition, the sample stage 2 includes a plurality of through-holes passing through the base material 2a, the adhesive layer 204, and the electrostatic chuck 201. The through-holes of the sample stage 2 of this example include a plurality of push-up pin holes 205 in which a push-up pin for vertically moving the sample 3 above the sample stage 3 in a state in which the sample is placed on the front end, and a plurality of heat transmission supply holes 207 in which heat transmission gas such as He, supplied to a gap between the back surface of the sample 3 and the top surface of the electrostatic chuck 201, flows in a state in which the sample 3 is placed on the top surface of the electrostatic chuck 201.

The electrostatic chuck 201 includes an adsorption plate 202 composed of a sintered plate formed by sintering aluminum oxide (Al₂O₃) or a ceramic material including the same in a predetermined shape, and a surface film 206 composing the top surface of the electrostatic chuck 201 by disposed as to cover the top surface of the adsorption plate 202, roughly classified. In the adsorption plate 202, a plurality of film-shaped electrodes 15 connected to the DC power supply 17 (not illustrated) through a low-pass filter 16 are disposed. The adsorption plate 202 of this example is formed by sintering a ceramic material, in which a material for the metal electrode 15 such as tungsten is disposed, inside a mold. In addition, as the temperature adjustment unit, a film in which a film-shaped electrode for the heater is disposed and which is made of a dielectric such as ceramic formed by a spraying method may be disposed between the adhesive layer 204 and the top surface of the base material 2a.

When the sample 3 placed on the front end of an arm of the transfer robot including an arm, which is disposed in the transfer chamber, connected to a plurality of arms, and configured to extend and contract, is transferred from the transport chamber connected to the vacuum chamber 10 to the processing chamber in the vacuum chamber 10, and is carried to the upper side of the sample stage 2, a plurality (in this example, three) of push-up pins accommodated in the plurality of push-up pin holes 207 in the sample stage 2 is moved upward by drive of a driving device (not illustrated) and is brought into contact with the back surface of the sample 3 held on the protruding arm by the front end of the push-up pin protruding upward from the top surface of the electrostatic chuck 201. In addition, as the push-up pin is moved upward, the sample 3 is lifted further upward and thus the sample 3 is transferred from the arm to the push-up pin. When the arm contracts and retracts from the inside of the vacuum chamber 11 to the transfer chamber, the gate of the vacuum chamber 11 is closed by the gate valve and is sealed. The sample 3 is placed on the top surface of the electrostatic chuck 201 as the push-up pin is moved downward and accommodated in the push-up pin hole 205 of the sample stage 3.

In this state, the power is supplied from the DC power supply to the electrodes 15, and the plurality of electrodes 15 have different polarities. Thereby, the sample 3 is adsorbed on the top surface of the electrostatic chuck 201 by positive and negative charges generated inside the electrostatic chuck 201 between the electrodes 15 and the sample 3. In this state, the refrigerant, reaching a predetermined temperature by supply of a gas such as He having heat transference between the back surface of the sample 3 and the top surface of the electrostatic chuck 201 through the heat transfer gas hole 207, is supplied to the refrigerant channel 19 and circulates through the refrigerant channel 19. The heat transfer between the refrigerant and the base material 2a whose temperature is adjusted by the circulation is accelerated.

Furthermore, the exhaust device connected to the exhaust opening disposed on the bottom surface of the processing chamber under the sample stage 2 is driven. Thereby, the processing chamber inside the vacuum chamber 11 is exhausted, and simultaneously the processing gas is supplied through the through-holes of the shower plate 5. The pressure in the processing chamber is adjusted to a value within a range suitable for start of the processing by a balance between the flow rate or the speed of the processing gas supplied into the processing chamber and the flow rate or the speed of the exhaust from the exhaust opening. The plasma forming high-frequency power is supplied from the high-frequency power supply for discharge 8 to the upper electrode 4, so that the plasma forming electric field is supplied into the processing chamber through the shower plate 5 formed of a dielectric such as quartz, and simultaneously the magnetic field formed by the electromagnetic coil 1 is supplied. The atoms or the molecules of the processing gas are excited and ionized or dissociated, so that the plasma 11 is formed above the sample stage 2 in the processing chamber.

Bias forming high-frequency power having a lower frequency than the plasma forming high-frequency power is supplied from a high-frequency power supply for bias 20 to the base material 2a, and a bias potential is formed above the top surface of the sample 3. Depending on a potential difference between the bias potential and the plasma 11, the charged particles such as ions in the plasma 11 are attracted to and collide with the surface of the sample 3, and the processing of the film for the processing target that has been previously disposed is started. When the processing of the sample 3 is advanced with the heat transfer between the processing target and the base material 2a adjusted to a temperature within a predetermined range by the refrigerant, an end point of the processing is detected by a determining instrument (not illustrated), thereby the supply of the bias forming high-frequency power to the base material 2a is stopped, and the processing is stopped so that the plasma 11 is extinguished. Afterward, after the electrodes 15 are given the polarities different from those during the processing and the electrostatic force by which the sample 3 is adsorbed is reduced, the push-up pins are driven upward, and the sample 3 is raised above the electrostatic chuck 201.

Afterward, in a state in which the arm of the transfer robot in the transfer chamber enters the processing chamber through the gate opened by driving the gate valve, and the tip of the arm is positioned between the sample 3 and the electrostatic chuck 201, the push-up pins are lowered again, and are accommodated in the push-up pin holes 205. Thereby, the sample 3 is transferred from the push-up pins to the tip of the arm. When the arm is ejected from the gate into the transfer chamber by contraction thereof, the sample 3 is placed on the arm, and is unloaded from the inside of the vacuum chamber 11. If there is a sample to be processed next, the next sample 3 is processed in the processing chamber by the operation as described above. If it is determined that there is no next sample 3 to be processed, the operation of the plasma processing apparatus of this example for the purpose of fabricating the semiconductor device is stopped.

As illustrated in FIG. 2B, the electrostatic chuck 201 of the present embodiment includes a plurality of protrusions or projected portions on the top surface thereof, and the sample 3 is placed above the top surface of the electrostatic chuck 201. The projected portions are protrusion portions that include an outer circumferential protruding part 305 that surrounds a central portion of the top surface of the adsorption plate 202 along the outer circumferential edge of the adsorption plate 202 and is disposed in a ring shape, a plurality of inner protruding portions 306 (three in this example) that surround the openings of the upper ends of the push-up pin holes 205 around these openings and are disposed in a ring shape, and that are disposed on the top surface of the adsorption plate 202 between the outer circumferential protruding part 305 and the inner protruding portions 306 and have a cylindrical or frustum shape. The projected portions include a plurality of columnar dot portions 304, upper end faces of which have smaller diameters than inner diameters of the inner protruding portions 306. The three push-up pin holes 205 of this example are formed around the center of the adsorption plate 202, the center of the opening of the upper end of which has a circular shape when the electrostatic chuck 201 is viewed from above, at the same angle or an angle approximated such as to be regarded as such, and are disposed at radius positions that are identical or equivalent from the center.

The plurality of dot portions 304 are formed in advance as 1300 dot portions such that distances thereof throughout the top surface of the adsorption plate 202 on the inner side of the outer circumferential protruding part 305 are not necessarily the same, but areas of the upper end faces thereof per unit area become the equal values or values approximated such as to be regarded as such, and heights H1 thereof are identical or equivalent to one another. Furthermore, the top surface of the adsorption plate 202 of the present embodiment are covered with a surface film 206 formed of a material made of a dielectric, including the outer circumferential protruding part 305 and the upper end faces of the inner protruding portions 306 other than the upper ends of the dot portion 304. In this state, the top surface of the adsorption plate 202 between the dot portions 304 is also covered with the surface film 206, and is made lower than the upper end faces of the dot portions 304 that do not have the surface film 206.

In FIG. 3, sizes and the number of dot portions 304 are modeled and illustrated, and the number of dot portions 304 illustrated is different from an actual number. When the sample 3 is placed on the top surface of the electrostatic chuck 201 and is subjected to electrostatic adsorption, the outer circumferential edge of the back surface of the sample 3 and the upper end face of the outer circumferential protruding part 305 come into contact with each other, and the adsorbing force is applied to both. A region between the gap between the back surface of the sample 3 and the top surface of the electrostatic chuck 201, and a space in the processing chamber on an outer circumferential side of the outer circumferential protruding part 305 is approximately airtightly partitioned, and the gas such as helium having heat transference is confined in the gap, and is inhibited from leaking into the processing chamber.

As illustrated in FIG. 3, the adsorption plate 202 of this example is a sintered plate that is formed by sintering a ceramic material including Al₂O₃, and includes the outer circumferential protruding part 305 which is disposed on the outer circumferential edge in a ring shape and in which a height of a flat upper end face having a width W in a radial direction is higher than the top surface of the central portion of the adsorption plate 202, and the dot portions 304 that are disposed on the inner side of the outer circumferential protruding part 305 and have cylindrical shapes in which heights of the upper end faces that are flat and cylindrical and have a diameter D is higher than the surroundings. The top surface of the adsorption plate 202 including the top surface of the outer circumferential protruding part 305 is covered with the surface film 206 that contains the ceramic material including yttrium oxide (Y₂O₃) excluding the top surfaces and sidewall surfaces of the dot portions 304 and a ring-shaped region of the top surface of the adsorption plate 202 around lower ends of sidewalls of the dot portions 304.

The surface film 206 is also disposed to cover a sidewall surface of the inner circumferential side and the top surface of the outer circumferential protruding part 305, and are covered without vacating the top surface of the adsorption plate 202 between the dot portions 304 and the outer circumferential protruding part 305. In this way, a top surface of the surface film 206 that covers the top surface of the adsorption plate 202 on the central side of the outer circumferential protruding part 305 has a height lower than the heights of the upper end faces of the dot portions 304, and forms a non-contact surface 301 in a state in which the sample 3 is placed on the electrostatic chuck 201 and is subjected to electrostatic adsorption. In the present embodiment, as illustrated in FIG. 3, a distance between them is denoted by H2, and is shorter than the height H1 from the top surface of the adsorption plate 202 around the dot portions 304.

As illustrated in FIG. 3, in this example, the electrodes 15 are disposed in a projection region below the outer circumferential protruding part 305 and the dot portions 304 inside the adsorption plate 202, and the charges formed by the direct current power supplied to the electrodes 15 are formed through the outer circumferential protruding part 305 and the dot portions 304. Thereby, a pressing force based on static electricity is configured to be applied between the top surfaces of them and the back surface of the sample 3 placed above them.

A region of the top surface of the ring-shaped adsorption plate 202 that includes the lower ends of the dot portions 304 of the present embodiment and surrounds them serves as an uncovered portion 303 in which a surface film 206 is not disposed. That is, the surface film 206 disposed around the dot portions 304 having a cylindrical shape is disposed at a distance from the lower ends of the sidewalls of the cylindrical dot portions 304. Thereby, the top surface of the adsorption plate 202 around the circular upper end faces and cylinder or frustum-like sidewalls, and the lower ends of the dot portions 304 is not in contact with the back surface of the sample 3 in a state in which the sample 3 is placed on the electrostatic chuck 201, and is exposed to the space in the processing chamber in a state in which the sample 3 is not placed in the space forming the gap between the sample 3 and the electrostatic chuck 201.

Furthermore, according to the present embodiment, the disk-shaped electrostatic chuck 201 has a diameter ϕ of 295 mm and a surface area of 683.1 cm². Also, the total area of a region 307 not covered by the surface film 206 is about 22.9 cm² (a sum of areas of the dot portion 304 and a portion around dots not coated with yttrium oxide x the number of the dots), and a coverage of yttrium oxide for the total area of the electrostatic adsorption surface is about 96.7%.

The surface film 206 according to the present embodiment is formed by using yttrium oxide (Y₂O₃) having a thickness of 5 μm through a PVD (Physical Vapor Deposition) process. Also, a height H1 of the dot portion 304 is 15 μm, and a diameter D thereof is 1 mm. Furthermore, a height difference H2 between a surface of the outer circumferential seal portion 302, which is the top surface of the surface film 206 covering the top surface of the outer circumference protruding part 305, and a non-contact surface 301 of the surface film 206 at the center of the outer circumference protruding part 305, is equal to the height of a step of the outer circumferential seal portion 302 and is 10 μm. Also, vertical heights of the upper end surface of the dot portion 304 and the top surface of the seal portion 302 are identical or sufficiently similar to each other. In other words, the upper end surface of the dot portion 304 and the top surface of the seal portion 302, which are located on a same plane, contact the back surface of the sample 3 while the sample 3 is being electrostatically absorbed onto the electrostatic chuck 201.

Furthermore, the diameter of the outer circumference end of the uncovered portion 303 not covered by the surface film 206 around the dot portion 304, that is, the diameter of the inner circumferential end of the surface film 206 surrounding the outer circumference of the dot portion 304 is within 1.5 times the diameter of the dot portion 304. In the present embodiment, since the diameter of the dot portion 304 having a cylindrical shape is 1 mm, the diameter ϕ of the uncovered portion 303 is 1.5 mm. Also, the width W of the outer circumferential protruding portion 305 is 3 mm.

As in the above embodiment, the top surface of the aluminum oxide adsorption plate 202 is covered with the surface film 206 made of yttrium oxide with a coverage of 90% or higher. Therefore, a portion exposed to the plasma 11 is remarkably reduced as compared to the related art, and a total amount of aluminum oxide in the adsorption plate 202 consumed by an interaction with particles in the plasma 11 may be reduced. As a result, due to actions of the aluminum oxide and the particles in the plasma 11, spread of metal species like aluminum (Al) and magnesium (Mg) into a processing chamber inside the vacuum chamber 10 may be prevented, and thus metal contamination of the sample 3 to be processed may be prevented.

The consumption of yttrium oxide by the plasma 11 is considerably less than that of aluminum oxide, and the diffusion of substances causing contamination into the processing chamber due to the consumption of yttrium oxide can be greatly reduced. The higher the coverage of the surface film 206 on the top surface of the adsorption plate 202, the greater the effect of preventing contamination. By covering 90% or more with the surface film 206 containing yttrium oxide as a main component, it is possible to sufficiently prevent contamination by metal.

In terms of the prevention of metal contamination only, it is preferable that the surface film 206 cover the entire top surface of the adsorption plate 202 including all surfaces of the dot portion 304. However, it is known that the mechanical strength of yttrium oxide is significantly lower than that of aluminum oxide. Therefore, when yttrium oxide is disposed at a position which comes into contact with the sample 3 by electrostatic adsorption, the yttrium oxide may be damaged or fractured by excessive stress locally generated by the contact or a pressing force between the yttrium oxide and the sample 3. As a result, fragments thereof are scattered inside the processing chamber and attached to the sample 3 or inner surfaces of other processing chambers and become foreign matter.

JP-A-2015-162490 discloses a technical configuration in which yttrium oxide is not disposed on the top portion of the top surface of the protruding portion corresponding to the dot portion 304 according to the present embodiment. According to this technical configuration, damages to a coating film on the top-portion top surface of the protruding portion at which generation of the largest stress is anticipated may be avoided. However, the height H1 of the dot portion 304 according to the present embodiment is set to be within the range from several μm to dozens of μm, and deviations in the heights H1 of the dot portions 304 throughout the top surface of the adsorption plate 202 is substantially inevitable. As a result, in some of the dot portions 304, stress is applied not only to the top portion of the dot portion 304, but also to a member constituting sidewall surfaces nearby the top surface of the top portion of the dot portion 304. Therefore, the surface film 206 containing yttrium oxide covering the sidewall surfaces is likely be damaged.

In the present embodiment, in order to prevent occurrence of contamination in the processing chamber or the sample 3 by damages to a surface film due to local stress associated with a contact with the sample 3, the surface film 206 containing yttrium oxide is not disposed on a surface of the ring-shaped adsorption plate 202 surrounding the top surface and the sidewall surfaces of the top portion of the dot portion 304 and the outer circumference of the lower end of the dot portion 304. Therefore, due to a stress generated on the top surface of the top portion of the dot portion 304 and nearby sidewall surfaces surrounding the outer circumferential end thereof as the sample 3 is brought into contact with or absorbed, the surface film 206 is damaged or fractured, thereby forming fragments or particles that become foreign matters.

In the above-described embodiment, as a process of forming the uncovered portion 303 which is not covered with the surface film 206 made of yttrium oxide on the surface of the dot portion 304 and the top surface of the adsorption plate 202 around thereof, the following two procedures are considered.

At the first procedure, first, yttrium oxide or a ceramic material containing yttrium oxide is applied on the entire top surface of the adsorption plate 202 of the electrostatic chuck 201 by PVD, thermal spraying, or the like. Next, a mask is provided on the top surface of the adsorption plate 202 in the dot portion 304 and in a predetermined region around the dot portion 304 to cover the surface film 206 on the electrostatic adsorption surface facing the sample 3. After that, the mask is removed, the mask in which only the dot portion 304 and its peripheral portion are opened is applied to the entire top surface covered with the surface film 206, and polishing is performed using sand blasting or an abrasive to remove only the surface film 206 at the opening of the mask.

At the second procedure, a mask is applied to only the dot portion 304 and a portion on the top surface of the adsorption plate 202 in the periphery thereof, a ceramic material containing yttrium oxide is applied on the entire top surface of the adsorption plate 202 by PVD, thermal spraying, or the like to form a film, and the surface film 206 is disposed. Next, the mask disposed to cover the dot portion 304 and the portion in the periphery thereof is removed to form the uncovered portion 303 not covered with the surface film 206.

In both the first and second procedures, it is necessary to dispose the mask to conform to each position of the dot portions 304 formed in advance on the top surface of the adsorption plate 202 made of aluminum oxide. Therefore, since the mask having a diameter same as the diameter of the top portion of the dot portion 304 needs to have high accuracy for positioning with respect to the dot portion 304, the manufacturing cost increases. When the diameter of the opening of the mask is set about 1.5 times the diameter of the dot portion 304, it is possible to prevent the cost from increasing due to the mask manufacturing and the mask arrangement, and further to improve the yield of manufacturing.

On the other hand, when the area of the uncovered portion 303 not covered with the surface film 206 becomes smaller than 10% of the entire area of the top surface of the electrostatic chuck 201 or the adsorption plate 202 facing the back surface of the sample 3 (the region covered with the surface film 206 is 90% or more), it is known that the contamination and the foreign matters occurred in the above-described embodiment are sufficiently prevented. Therefore, by setting the diameter of the outer circumferential edge (the inner circumferential edge of the surface film 206 surrounding the periphery of the dot portion 304) of the uncovered portion 303 to be within 1.5 times the diameter of the lower end portion of the dot portion 304, the cost for covering with the surface film 206 to manufacture the electrostatic chuck 201 is reduced.

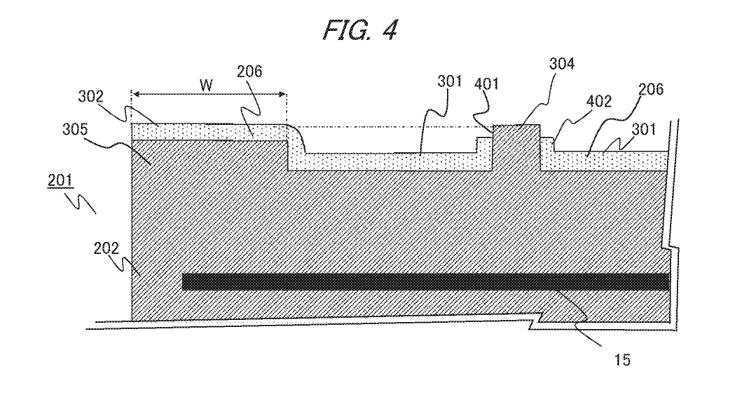

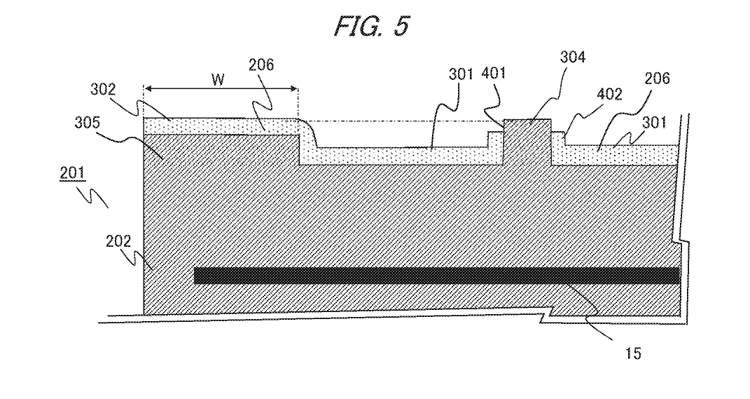

The configuration of a modification of the above embodiment will be described with reference to FIGS. 4 and 5. FIG. 4 is an enlarged longitudinal sectional view schematically illustrating a part of the structure of an electrostatic chuck of a sample stage of a plasma processing apparatus according to a modification of the above-described embodiment of the invention illustrated in FIG. 1. FIG. 5 is an enlarged longitudinal sectional view schematically illustrating a part of the structure of an electrostatic chuck of a sample stage of a plasma processing apparatus according to another modification of the above-described embodiment of the invention illustrated in FIG. 1.

In the example illustrated in FIG. 4, the top-portion top surface of the dot portion 304 and the side wall surface 401 of the dot portion 304 around the outer circumferential edge of the top surface are not provided with the surface film 206. The dot portion 304 in this example is configured such that when the top surface of the top thereof and the side wall surface 401 are placed in the processing chamber in a state where the sample 3 is not placed on the electrostatic chuck 201, the side wall surface 401 is exposed to the space of the gap between the sample 3 and the top surface of the electrostatic chuck 201.

That is, the side-wall surface of the dot portion 304 is provided with a side-wall covering portion 402 of the surface film 206 covering the side-wall surface from the lower end to a predetermined height lower than the outer circumference of the top-portion top surface. The upper end of the side-wall covering portion 402 has a height higher than that of a non-contact surface 301 around the dot portion 304, and the upper end is formed to have a distance from the top-portion top surface of the dot portion 304, so that the sample 3 and the electrostatic chuck 201 are not in contact with each other even in the state where the sample 3 is placed on the electrostatic chuck 201 to be adsorbed.

Further, in a modification illustrated in FIG. 5, aside wall of the dot portion 304 is covered with the surface film 206 including the lower end portion, and an example is illustrated in which the thickness of the surface film 206 is set such that the surface film 206 is flush with a non-contact portion 301 at a place where the non-contact surface 301 of the surface film 206 and the side wall of the dot portion 304 are in contact with each other.

In both these modifications, the side wall surface of the dot portion 304 is covered with the surface film 206 up to a position lower than the outer circumferential edge of the top-portion top surface formed flat of the dot portion 304. As a result, due to variations in the height of the top-portion top surface of the dot portion 304 on the entire top surface of the electrostatic chuck 201, the same effect as in the above example is achieved that deformation of the top portion of the dot portion 304 when the sample 3 is absorbed, and the occurrence of contamination and foreign matters due to occurrence of chipping or cracking of the contact film 206 caused when the surface film 206 covering the side wall surface and the lower part of the corresponding side wall surface of the dot portion 304 is brought into contact with the back surface of the sample 3 accompanied by the deformation is reduced. In these modifications, since the coverage of the surface film 206 with respect to the top surface of the adsorption plate 202 is higher than that of the embodiment, the effect of preventing the generation of contamination and foreign matters is further enhanced. However, it is necessary to precisely form the surface film 206 on the side wall surface of the dot portion 304. In order to achieve the precision, it is necessary to form and arrange the mask with high accuracy in the step of covering the surface film 206, thereby increasing the manufacturing cost.

In the example described above, the height H1 of the dot portion 304 is set to 15 μm. With the set height, it is prevented that the sample 3 and the top surface of the non-contact surface 301 of the electrostatic chuck 201 are contact with each other by the dot portion 304, thereby preventing an occurrence of a foreign matter caused by the electrostatic chuck 201 on the sample 3.

However, if the height H1 of the dot portion 304 is higher than necessary, the amount and the efficiency of heat transfer between the sample 3 and the electrostatic chuck 201 and the sample stage 2 are lowered, whereby the performance of adjusting the temperature of the sample 3 deteriorates. Accordingly, the height of the dot portion 304 is preferably set to equal to or less than 20 μm in the embodiment.

Likewise, in the above example, the diameter of the top-portion top surface of the dot portion 304 having a cylindrical shape or a truncated cone shape is set to 1 mm. When the diameter of the dot portion 304 is large, it is necessary to reduce the number of the dot portions 304 in order to make the coverage of the surface film 206 90% or more. When the number of the dot portions 304 decreases and the distance between the dot portions 304 increases, there is a high possibility that the sample 3 comes into contact with the non-contact surface 301 of the surface film 206 in a state where the sample 3 is electrostatically adsorbed, whereby the effect of preventing contamination and foreign matters on the sample 3 deteriorates.

According to the study by the inventors, in order to reduce such contact between the sample 3 and the non-contact surface 301, it is obtained as knowledge that the dot portion 304 needs to be arranged as evenly as possible in a region other than the seal portion 302, and about 300 pieces of the dot portions are necessary on the top surface of the adsorption plate 202 having a diameter of about 300 mm. In order to make this condition and the area of the uncovered portion 303 smaller than 10% of the area of the top surface of the adsorption plate 22, the diameter of the top-portion top surface of the dot portion 304 needs to be 2 mm or less.

Further, in the above example, the thickness of the seal portion 302 and the non-contact surface 301 of the surface film 206 is 5 μm. This thickness is required to be compatible with the cost for forming the surface film 206 and the lifetime of the surface film 206, and is preferably selected from the range of 2 μm to 10 μm. In addition, although PVD is used for the surface film 206, it is needless to say that other methods such as CVD (Chemical Vapor Deposition) and thermal spraying also have similar effects.

In the embodiment described above, a sintered plate which is sintered using a material mainly composed of aluminum oxide is used as the adsorption plate 202. The thickness from the electrode 15 disposed inside the adsorption plate 202 to the top surface contact with the sample 3 is substantially set to 200 μm to 300 μm.

Therefore, the surface film 206 is arranged as a layer having a minute thickness on the surface of the electrostatic chuck 201. With such a configuration, when Coulomb type electrostatic adsorption is performed by the electrode 15, by forming the adsorption plate 202 mainly with aluminum oxide having high withstanding voltage characteristics and high deposition resistivity, high adsorption characteristics due to high voltage application can be realized, and residual adsorption caused by low leak current can be effectively prevented.

According to the above embodiment, even when the top portion of the dot portion 304 and the back surface of the sample 3 come into contact with each other to deform the top portion when the sample 3 is electrostatically attracted to the electrostatic chuck 201, it is prevented that the surface film 206 covering the dot portion 304 is damaged or missed and then adhered to the sample 3 to be a foreign matter, so that the yield of processing on the sample 3 deteriorates. Further, damage of the surface film 206 on the top surface of the electrostatic chuck 201 is reduced, and the time interval for repairing and maintaining the electrostatic chuck 201 or the base material 2a is lengthened, so that the processing efficiency is improved.

1. A plasma processing apparatus in which a sample as a processing target placed and held on a sample stage is processed using plasma formed inside a processing chamber, the sample stage being disposed inside the processing chamber inside a vacuum chamber, wherein
a plate-like member, which is disposed on the sample stage, constitutes a top surface placed with the sample, and is formed of a first dielectric, includes: an outer circumferential protruding portion disposed in a ring shape surrounding a central portion on the top surface of the plate-like member along an outer circumferential edge; a plurality of columnar projections which are arranged on the top surface of the plate-like member on the central side of the outer circumferential protruding portion; and a film formed of a second dielectric which covers the top surface of the plate-like member on the central side of the outer circumferential protruding portion, a top-portion top surface of the projections, and a top surface of the plate-like member excluding a sidewall surface extending from an outer circumferential edge of the top-portion top surface.

2. The plasma processing apparatus according to claim 1, wherein
the film formed of the second dielectric is disposed to cover a top surface of the outer circumferential protruding portion, and the sample is placed and held on a top surface of the film formed of the second dielectric disposed on the outer circumferential protruding portion and top surfaces of a plurality of the projections.

3. The plasma processing apparatus according to claim 1, wherein
a gap is formed between the top surface of the film formed of the second dielectric disposed on a center side of the outer circumferential protruding portion and the sample, and the sample is placed on the projection to be held on the sample stage.

4. The plasma processing apparatus according to claim 1, wherein
the film formed of the second dielectric is disposed to cover the top surface of the plate-like member excluding the top surface of the plate-like member in the periphery including a lower end of the projection.

5. The plasma processing apparatus according to claim 1, wherein
the height of the projection is equal to or less than 20 μm and a diameter of the top-portion top surface is equal to 2 mm or less.

6. The plasma processing apparatus according to claim 1, wherein
the thickness of the second dielectric film is set to 2 μm to 10 μm.

7. The plasma processing apparatus according to claim 1, wherein
a ratio of an area of a portion covered with the film formed of the second dielectric on the top surface of the plate-like member with respect to an area of the entire top surface is 90% or more.

8. The plasma processing apparatus according to claim 1, wherein
the first dielectric contains aluminum oxide and the second dielectric contains yttrium oxide.
